(19) United States
(12) Patent Application Publication
(10) Pub. No.: US 2026/0052647 A1
(43) Pub. Date: Feb. 19, 2026

(54) COOLANT SUPPLY ASSEMBLY

(71) Applicant: MANN+HUMMEL GmbH, Ludwigsburg (DE)

(72) Inventors: Ming PENG, Shanghai (CN); Yuyu GAO, Shanghai (CN); Lei WU, Shanghai (CN)

(21) Appl. No.: 19/304,117

(22) Filed: Aug. 19, 2025

Related U.S. Application Data
(63) Continuation of application No. PCT/CN2024/111638, filed on Aug. 13, 2024.

(51) Int. Cl. H05K 7/20; B01D 29/11; B01D 29/56; B01D 29/60; B01D 35/147; B01D 35/26; B01D 35/30; B01D 36/00

(52) U.S. Cl. CPC H05K 7/20327; B01D 29/114; B01D 29/56; B01D 29/605; B01D 29/606; B01D 29/608; B01D 35/1475; B01D 35/26; B01D 35/306; B01D 36/003; H05K 7/203; B01D 2201/16; B01D 2201/4092; H05K 7/20309

(57) ABSTRACT

A coolant supply assembly includes an upper housing including a pre-filter mounting portion, a desiccant mounting portion, a pump mounting portion, and a main filter mounting portion on a top surface of the upper housing, the upper housing further including a flange portion at a first side surface of the upper housing and a coolant outlet at a second side surface opposite to the first side surface. The coolant supply assembly further includes a lower housing, the upper housing being mounted to the lower housing to define a coolant chamber, a pre-filter device mounted to the pre-filter mounting portion, a desiccant unit mounted to the desiccant mounting portion, a pump mounted to the pump mounting portion, a heat exchanger mounted to the flange portion, and a main filter device mounted to the main filter mounting portion.

### CROSS-REFERENCE TO RELATED APPLICATION

This application is a continuation application of international application No. PCT/CN2024/111638 having an international filing date of Aug. 13, 2024, and designating the United States, the entire contents of the aforesaid application being incorporated herein by reference.

### TECHNICAL FIELD

Embodiments relate to a coolant supply assembly, and more specifically to a coolant supply assembly for an immersion liquid cooling system.

### BACKGROUND

With the fast development of the information industry, big data services, new energy storage and related infrastructure, the cooling demand of data centers, servers, charging piles and other facilities continues to increase, and immersion liquid cooling technology is gaining more and more attention. In immersion liquid cooling method, a heat generation module is completely immersed in coolant liquid, heat generated by the heat generation module is dissipated through the coolant liquid, and the coolant liquid is cooled through a cooling pipe of the heat exchanger to achieve the effect of continuous circulating cooling. The immersion liquid cooling technology is advantageous in that the heat conduction resistance is low, and the heat dissipation efficiency is greatly improved.

However, during use of the coolant liquid, the coolant liquid may contain various impurities, such as particles, water, and vapor, for example precipitated substances from other components (such as heat exchanger, heat generation module) of a cooling circuit, thus physical and chemical properties of the coolant liquid for immersion liquid cooling may vary over time, which may negatively influence normal operation of other components.

To this end, it is desirable to develop a coolant supply assembly that is simple in structure and can reliably remove three-phase impurities from the coolant liquid, thereby improving the efficiency and service life of the immersion liquid cooling system.

### SUMMARY

An object of the present disclosure is to provide a coolant supply assembly that is simple in structure and may reliably remove three-phase impurities from the coolant liquid, thereby improving the efficiency and service life of the immersion liquid cooling system.

In one aspect, a coolant supply assembly is provided. The coolant supply assembly includes an upper housing including a pre-filter mounting portion, a desiccant mounting portion, a pump mounting portion, and a main filter mounting portion on a top surface of the upper housing, the upper housing further including a flange portion at a first side surface of the upper housing and a coolant outlet at a second side surface opposite to the first side surface. The coolant supply assembly further includes a lower housing, the upper housing being mounted to the lower housing to define a coolant chamber, a pre-filter device mounted to the pre-filter mounting portion, a desiccant unit mounted to the desiccant mounting portion, a pump mounted to the pump mounting portion, a heat exchanger mounted to the flange portion, and a main filter device mounted to the main filter mounting portion.

The desiccant unit may include a shell, an upper cover mounted to a top end of the shell, a lower cover mounted to a bottom end of the shell, a gas phase filter molecular sieve, and a liquid phase filter molecular sieve. The upper cover, the lower cover and the shell may form an internal volume, the gas phase filter molecular sieve being disposed in an upper portion of the internal volume, and the liquid phase filter molecular sieve being disposed in a lower portion of the internal volume.

The desiccant unit may further include a spring and a regulator, the spring and the regulator being configured to cooperate to automatically adjust a vertical position of the gas phase filter molecular sieve and the liquid phase filter molecular sieve.

The regulator may include a bottom plate portion disposed on top of the liquid phase filter molecular sieve, and a plurality of elastic arms extending axially from the bottom plate portion, an outer diameter of the bottom plate portion being smaller than an inner diameter of the shell, and each of the plurality of elastic arms including a projection extending radially outward from an end of a respective one of the plurality of elastic arms, the end being distant from the bottom plate portion.

The shell may include a plurality of axial grooves receiving the projection of each of the plurality of elastic arms, respectively. The spring may be disposed between the bottom plate portion and a bottom surface of the gas phase filter molecular sieve.

The desiccant unit may have a rectangular cross-section or a circular cross-section.

The coolant supply assembly may further include a pressure relief valve configured to open a bypass passage upstream of the main filter device, when a pressure upstream of the main filter device exceeds a predetermined pressure.

The coolant supply assembly may further include a liquid level sensor disposed on the second side surface of the coolant supply assembly and configured to sense a level of coolant liquid in the coolant chamber. The coolant supply assembly may be configured to turn off the pump and trigger an alarm when the level of the coolant liquid is below a predetermined level.

The coolant supply assembly may further include an electric conductivity sensor disposed in the coolant chamber and configured to sense an electric conductivity of coolant liquid in the coolant chamber. The coolant supply assembly may be configured to turn off the pump and trigger an alarm when the electric conductivity of the coolant liquid exceeds a predetermined electric conductivity.

The coolant supply assembly may further include an outlet sensor disposed in an outlet passage and configured to sense a temperature and/or a pressure of coolant liquid in the outlet passage. The coolant supply assembly may be configured to control the pump according to the temperature and/or the pressure of the coolant liquid in the outlet passage.

The coolant supply assembly may have a rectangular cross-section including the first side surface, the second side surface, a third side surface extending between the first side surface and the second side surface and adjacent to the pre-filter mounting portion, and a fourth side surface opposite to the third side surface.

The pre-filter mounting portion may be located at a corner between the second side surface and the third side surface, the desiccant mounting portion may be located at a corner between the second side surface and the fourth side surface, the pump mounting portion may be located at a corner between the first side surface and the fourth side surface, and the main filter mounting portion may be located at a corner between the first side surface and the third side surface.

The heat exchanger may include an evaporator.

The coolant supply assembly may further include a breathing valve.

In another aspect, an immersion liquid cooling system including the coolant supply assembly is provided.

By means of the above layout of the coolant supply assembly, overall space is reduced, various connection pipes and/or hoses are omitted, and assembly time and cost are greatly reduced.

The spring and the regulator cooperate to automatically adjust vertical position of the gas phase filter molecular sieve and the liquid phase filter molecular sieve, to reduce relative movement between the gas phase filter molecular sieve and the liquid phase filter molecular sieve, thereby reducing the wear between the gas phase filter molecular sieve and the liquid phase filter molecular sieve and lengthening the useful life of the gas phase filter molecular sieve and the liquid phase filter molecular sieve.

In addition, if the level of the coolant liquid increases, floating force acting on the bottom plate portion also increases, which will resist the spring force of the spring, thus causing the spring to be further compressed, thus urging the gas phase filter molecular sieve upward. In this way, the gas phase filter molecular sieve is always above the level of the coolant liquid, thereby preventing failure of the gas phase filter molecular sieve due to immersing in the coolant liquid.

By integrating the pre-filter device, the desiccant unit and the main filter device, the coolant supply assembly may reliably remove three-phase impurities from the coolant liquid, thereby improving the efficiency and service life of the immersion liquid cooling system.

By integrating the pressure relief valve, the breathing valve, the liquid level sensor, the outlet sensor, the electric conductivity sensor and the inlet pressure sensor, the coolant supply assembly may be reliably operated, thereby improving the efficiency and service life of the immersion liquid cooling system.

Further areas of applicability of the present disclosure will become apparent from the following detailed description and the accompanying drawings. The detailed description and specific examples are intended for purposes of illustration only and are not intended to limit the scope of the disclosure.

### BRIEF DESCRIPTION OF THE DRAWINGS

The present disclosure will become more fully understood from the following detailed description and the accompanying drawings.

FIG. 1 is a schematic perspective view of a coolant supply assembly according to exemplary embodiments.

FIG. 2 is a schematic top view of a coolant supply assembly according to exemplary embodiments, showing section lines A-A, B-B, C-C, D-D, and E-E.

FIG. 3 is a schematic sectional view of the coolant supply assembly of FIG. 2 taken along section line A-A.

FIG. 4 is a schematic sectional view of the coolant supply assembly of FIG. 2 taken along section line B-B.

FIG. 5 is a schematic sectional view of the coolant supply assembly of FIG. 2 taken along section line C-C.

FIG. 6 is a schematic sectional view of the coolant supply assembly of FIG. 2 taken along section line D-D.

FIG. 7 is a schematic sectional view of the coolant supply assembly of FIG. 2 taken along section line E-E.

FIG. 8 is a schematic perspective view of an upper housing of the coolant supply assembly of FIG. 1.

FIG. 9 is a schematic perspective view of a lower housing of the coolant supply assembly of FIG. 1.

FIG. 10 is a schematic perspective view of a pre-filter device of the coolant supply assembly of FIG. 1.

FIG. 11 is a schematic perspective view of a main filter device of the coolant supply assembly of FIG. 1.

FIG. 12 is a schematic perspective view of a pump of the coolant supply assembly of FIG. 1.

FIG. 13 is a schematic perspective view of a heat exchanger of the coolant supply assembly of FIG. 1.

FIG. 14 is a schematic perspective view of a desiccant unit of the coolant supply assembly of FIG. 1.

FIG. 15 is a schematic perspective view of a desiccant unit of the coolant supply assembly according to another exemplary embodiment.

FIG. 16 is a schematic perspective view of a breathing valve of the coolant supply assembly of FIG. 1.

FIG. 17 is a schematic perspective view of a pressure relief valve of the coolant supply assembly of FIG. 1.

FIG. 18 is a schematic perspective view of various sensors of the coolant supply assembly of FIG. 1.

FIG. 19 is a schematic perspective view of a regulator of the desiccant unit of FIG. 15.

### DETAILED DESCRIPTION

The following detailed description is merely exemplary in nature and is not intended to limit the present disclosure, application, or uses. It should be understood that throughout the drawings, corresponding reference numerals indicate like or corresponding parts and features. Additionally, the drawings are generally schematic and not necessarily to scale. Some features may be exaggerated or minimized to show details of particular components. Therefore, specific structural and functional details disclosed herein are not to be interpreted as limiting, but merely as a representative basis for teaching one skilled in the art to variously employ the present disclosure.

Certain terminology may be used in the following description for the purpose of reference only and thus are not intended to be limiting. For example, terms such as “above” and “below” refer to directions in the drawings to which reference is made. Terms such as “front”, “back”, “fore”, “aft”, “left”, “right”, “rear”, “side”, “upward”, “downward”, “horizontal”, “vertical”, “top”, and “bottom”, etc., describe the orientation and/or location of portions of the components or elements within a consistent but arbitrary frame of reference, which is made clear by reference to the text and the associated drawings describing the components or elements under discussion.

Furthermore, terms such as “first”, “second”, “third”, and so on may be used to describe separate components. Such terminologies are used descriptively for the drawing figures, and do not represent limitations on the scope of the disclosure, as defined by the appended claims.

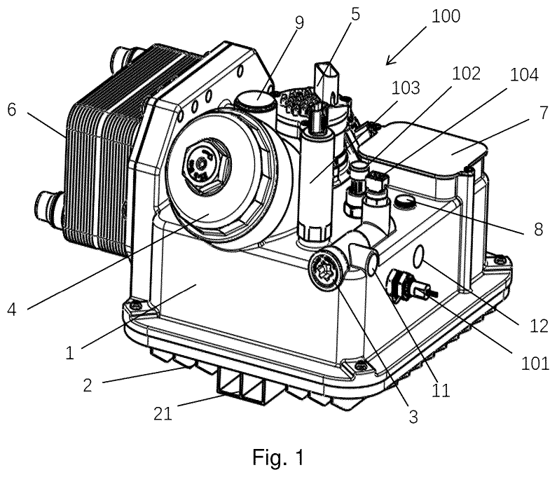

Referring now to the drawings, wherein like reference numbers refer to like features throughout the several views, FIG. 1 is a schematic perspective view of a coolant supply assembly 100 according to exemplary embodiments.

According to one example, the coolant supply assembly 100 may comprise an upper housing 1; a lower housing 2, the upper housing 1 being mounted to the lower housing 2 to define a coolant chamber; a pre-filter device 3; a desiccant unit 7; a pump 5; a heat exchanger 6; and a main filter device 4.

According to one example, the coolant supply assembly 100 may further comprise a pressure relief valve 9; a breathing valve 8; a liquid level sensor 101; an outlet sensor 102; an electric conductivity sensor 103; and an inlet pressure sensor 104. As understood by those skilled in the art, the coolant supply assembly 100 may further comprise any other suitable components, such as a controller and/or additional sensors, without departing from the intended scope of the disclosure.

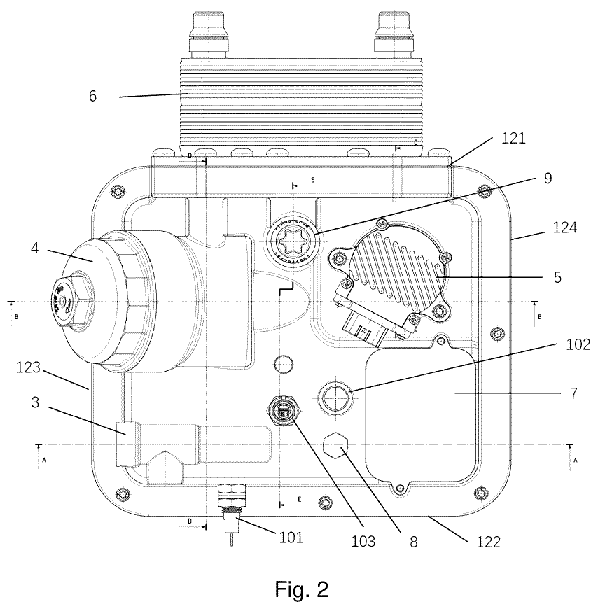

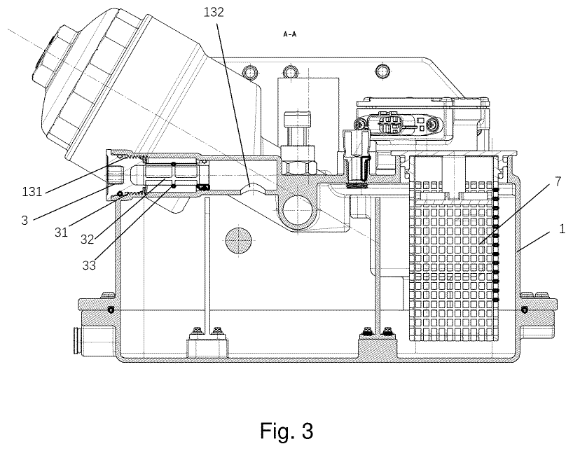

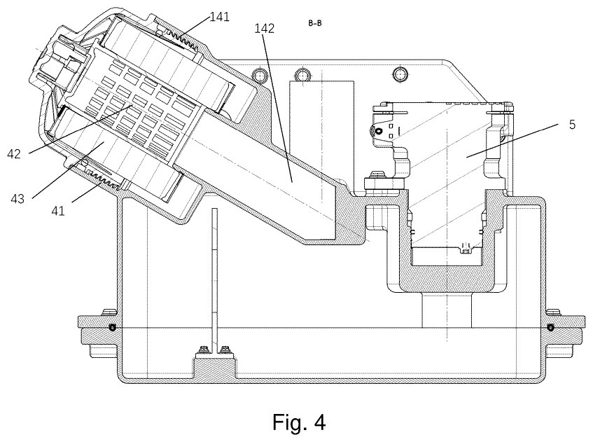

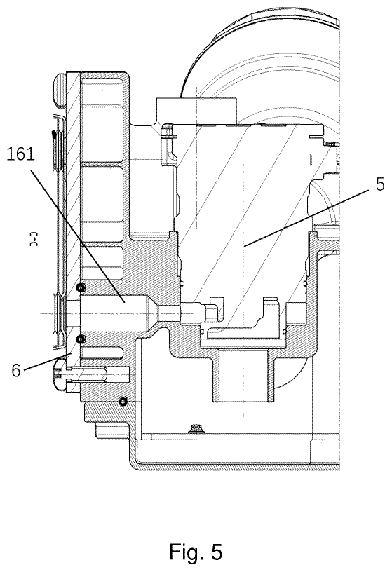

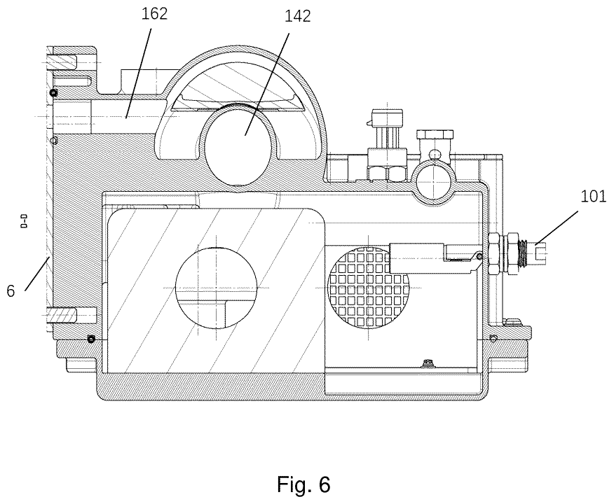

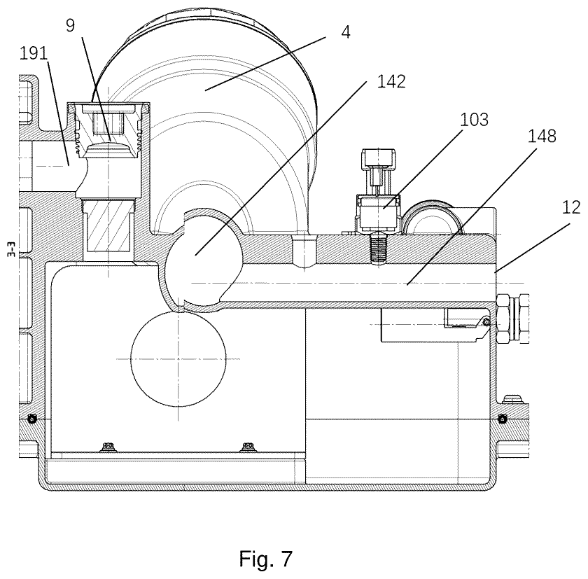

FIG. 2 is a schematic top view of a coolant supply assembly 100 according to exemplary embodiments, showing section lines A-A, B-B, C-C, D-D, and E-E. FIG. 3 is a schematic sectional view of the coolant supply assembly 100 of FIG. 2 taken along section line A-A. FIG. 4 is a schematic sectional view of the coolant supply assembly 100 of FIG. 2 taken along section line B-B. FIG. 5 is a schematic sectional view of the coolant supply assembly 100 of FIG. 2 taken along section line C-C. FIG. 6 is a schematic sectional view of the coolant supply assembly 100 of FIG. 2 taken along section line D-D. FIG. 7 is a schematic sectional view of the coolant supply assembly 100 of FIG. 2 taken along section line E-E.

According to one example, the coolant supply assembly 100 has a rectangular cross-section comprising a first side surface 121, a second side surface 122, a third side surface 123 extending between the first side surface 121 and the second side surface 122 adjacent to a pre-filter mounting portion 130, and a fourth side surface 124 opposite to the third side surface 123. As understood by those skilled in the art, the coolant supply assembly 100 may have any other suitable cross-section, such as circular cross-section or semi-circular cross-section, without departing from the intended scope of the disclosure.

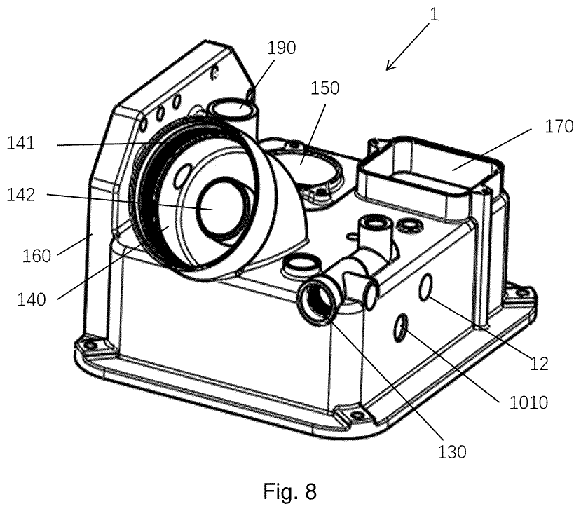

FIG. 8 is a schematic perspective view of an upper housing 1 of the coolant supply assembly 100 of FIG. 1. The upper housing 1 is provided with a pre-filter mounting portion 130, a desiccant mounting portion 170, a pump mounting portion 150, a main filter mounting portion 140 on a top surface thereof, a flange portion 160 at the first side surface 121 and a coolant outlet 12 at the second side surface 122 opposite to the first side surface 121. The pre-filter mounting portion 130 is located at a corner between the second side surface 122 and the third side surface 123, the desiccant mounting portion 170 is located at a corner between the second side surface 122 and the fourth side surface 124, the pump mounting portion 150 is located at a corner between the first side surface 121 and the fourth side surface 124, and the main filter mounting portion 140 is located at a corner between the first side surface 121 and the third side surface 123.

The pre-filter device 3 is mounted to the pre-filter mounting portion 130. According to one example, as shown in FIG. 3, the pre-filter device 3 is provided with a filter body 33 containing a filter element 32, and threads 31 at outer end of the filter body 33. The pre-filter mounting portion 130 is provided with a coolant inlet 11 configured to receive coolant liquid returning back from a heat generation module, an outlet port 132 configured to supply the filtered coolant liquid to the coolant chamber, and mating threads 131. Thus, the pre-filter device 3 is mounted to the pre-filter mounting portion 130 by thread engagement. As understood by those skilled in the art, the pre-filter device 3 may be mounted to the pre-filter mounting portion 130 by any other suitable means, such as snap connection, without departing from the intended scope of the disclosure.

The desiccant unit 7 is mounted to the desiccant mounting portion 170. The pump 5 is mounted to the pump mounting portion 150, and the heat exchanger 6 is mounted to the flange portion 160 and receives coolant liquid to be cooled from the pump 5 via a heat exchanger inlet passage 161 (FIG. 5).

The main filter device 4 is mounted to the main filter mounting portion 140. According to one example, as shown in FIG. 4, the main filter device 4 is provided with a main filter body, a main filter element 42, and threads 41 at an outer circumference of the main filter body. There is an annular unfiltered space 43 between the main filter body and the main filter element 42, which is configured to receive cooled coolant liquid from the heat exchanger 6 via a heat exchanger outlet passage 162 (FIG. 6). The main filter mounting portion 140 is provided with mating threads 141 and a filter outlet passage 142 in communication with the outlet passage 148 (FIG. 7). Thus, the main filter device 4 is mounted to the main filter mounting portion 140 by thread engagement. As understood by those skilled in the art, the main filter device 4 may be mounted to the main filter mounting portion 140 by any other suitable means, such as snap connection, without departing from the intended scope of the disclosure.

By means of the above layout of the coolant supply assembly 100, an overall space is reduced, various connection pipes and/or hoses are omitted, and assembly time and cost are greatly reduced.

The pressure relief valve 9 is mounted in a pressure relief port 190 (FIG. 8) and is configured to open a bypass passage 191 (FIG. 7) upstream of the main filter device 4 when a pressure upstream of the main filter device 4 exceeds a predetermined pressure.

The liquid level sensor 101 is disposed in a sensor port 1010 on the second side surface 122 of the coolant supply assembly 100 and configured to sense a level of the coolant liquid in the coolant chamber. The coolant supply assembly 100 turns off the pump 5 and triggers an alarm when the level of the coolant liquid is below a predetermined level.

The electric conductivity sensor 103 is disposed in the coolant chamber and configured to sense electric conductivity of the coolant liquid in the coolant chamber. The coolant supply assembly 100 turns off the pump 5 and triggers an alarm when the electric conductivity of the coolant liquid exceeds a predetermined electric conductivity.

The outlet sensor 102 is disposed in the outlet passage 148 and configured to sense temperature and/or pressure of the coolant liquid in the outlet passage 148. The coolant supply assembly 100 controls the pump 5 according to the temperature and/or pressure of the coolant liquid in the outlet passage 148.

The pre-filter device 3 and the main filter device 4 are particle filters, and the pre-filter device 3 is configured to filter out impurities in the coolant liquid returning back from a heat generation module. According to one example, the coolant supply assembly 100 may be used in an immersion liquid cooling system for electric vehicles, and the heat generation module may be a battery module used in electric vehicles. As understood by those skilled in the art, the coolant supply assembly 100 may be used in any other suitable immersion liquid cooling system, such as an immersion liquid cooling system for a big-data server, without departing from the intended scope of the disclosure. The main filter device 4 is configured to filter out impurities in the coolant liquid from the heat exchanger 6.

By integrating the pre-filter device 3, the desiccant unit 7 and the main filter device 4, the coolant supply assembly 100 reliably removes three-phase impurities from the coolant liquid, thereby improving the efficiency and service life of the immersion liquid cooling system.

By integrating the pressure relief valve 9, the breathing valve 8, the liquid level sensor 101, the outlet sensor 102, the electric conductivity sensor 103 and the inlet pressure sensor 104, the coolant supply assembly 100 is reliably operated, thereby improving the efficiency and service life of the immersion liquid cooling system.

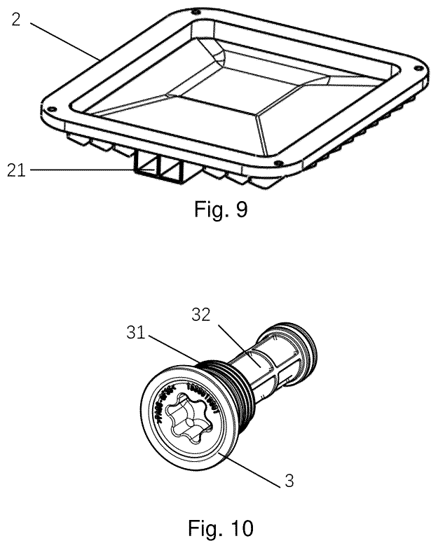

FIG. 9 is a schematic perspective view of the lower housing 2 of the coolant supply assembly 100 of FIG. 1. The lower housing 2 is provided with a draining hole 21 for draining used coolant liquid to exchange the coolant liquid.

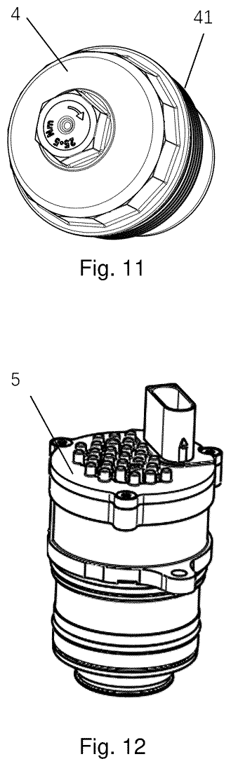

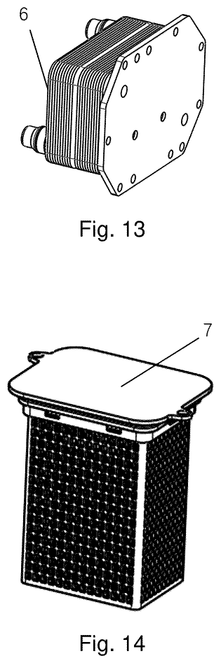

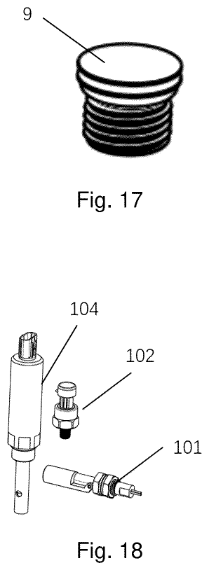

FIG. 10 is a schematic perspective view of the pre-filter device 3 of the coolant supply assembly 100 of FIG. 1. FIG. 11 is a schematic perspective view of the main filter device 4 of the coolant supply assembly 100 of FIG. 1. FIG. 12 is a schematic perspective view of the pump 5 of the coolant supply assembly 100 of FIG. 1. FIG. 13 is a schematic perspective view of the heat exchanger 6 of the coolant supply assembly 100 of FIG. 1, wherein the heat exchanger 6 is an evaporator. As understood by those skilled in the art, the heat exchanger 6 may be of any other suitable form, without departing from the intended scope of the disclosure. FIG. 14 is a schematic perspective view of the desiccant unit 7 of the coolant supply assembly 100 of FIG. 1. FIG. 16 is a schematic perspective view of the breathing valve 8 of the coolant supply assembly 100 of FIG. 1. FIG. 17 is a schematic perspective view of the pressure relief valve 9 of the coolant supply assembly 100 of FIG. 1.

According to one example, the desiccant unit 7 may have a rectangular cross-section. As understood by those skilled in the art, the desiccant unit 7 may have any other suitable cross-section, such as a circular cross-section, without departing from the intended scope of the disclosure.

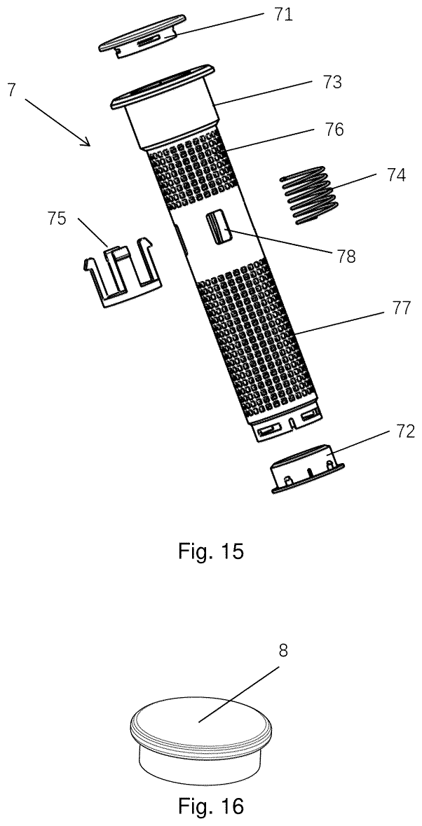

FIG. 15 is a schematic perspective view of the desiccant unit 7 of the coolant supply assembly 100 according to another embodiment. The desiccant unit 7 may comprise a shell 73, an upper cover 71 mounted to a top end of the shell 73, a lower cover 72 mounted to a bottom end of the shell 73, a gas phase filter molecular sieve 76, and a liquid phase filter molecular sieve 77, wherein the upper cover 71, the lower cover 72 and the shell 73 form an internal volume. The gas phase filter molecular sieve 76 is disposed in an upper portion of the internal volume, and the liquid phase filter molecular sieve 77 is disposed in a lower portion of the internal volume. Although the desiccant unit 7 shown in FIG. 15 has a circular cross-section, as understood by those skilled in the art, the desiccant unit 7 may have any other suitable cross-section, such as a rectangular cross-section, without departing from the intended scope of the disclosure. The gas phase filter molecular sieve 76 is above the level of the coolant liquid, so as to absorb impurities and vapor in the air above the coolant liquid to prevent impurities from dissolving in the coolant liquid, resulting in an increase in the dielectric constant of the coolant liquid. The liquid phase filter molecular sieve 77 is disposed in the coolant liquid, so as to absorb moisture and other conductive impurities in the coolant liquid.

The upper cover 71 and the lower cover 72 may be mounted to the shell 73 by thread engagement or snap connection. As understood by those skilled in the art, the upper cover 71 and the lower cover 72 may be mounted to the shell 73 by any other suitable means, without departing from the intended scope of the disclosure.

The desiccant unit 7 may further comprise a spring 74 and a regulator 75, the spring 74 and the regulator 75 cooperate to automatically adjust the vertical position of the gas phase filter molecular sieve 76 and the liquid phase filter molecular sieve 77.

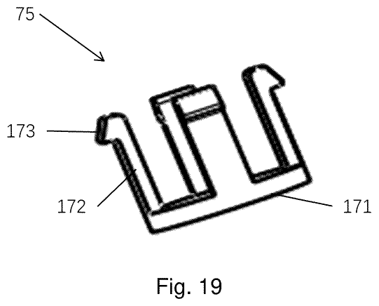

FIG. 19 is a schematic perspective view of the regulator 75 of the desiccant unit 7 of FIG. 15. The regulator 75 may comprise a bottom plate portion 171 disposed on top of the liquid phase filter molecular sieve 77, and a plurality of elastic arms 172 extending axially from the bottom plate portion 171. An outer diameter of the bottom plate portion 171 is slightly smaller than an inner diameter of the shell 73. Each elastic arm 172 is provided with a projection 173 extending radially outward from an end of the elastic arm 172 distant from the bottom plate portion 171. The shell 73 is provided with a plurality of axial grooves 78 (FIG. 15) configured to receive a respective projection 173. The spring 74 is disposed between the bottom plate portion 171 and a bottom surface of the gas phase filter molecular sieve 76. As shown in FIG. 15, there are four elastic arms 172 and four axial grooves 78, as understood by those skilled in the art, the number of the elastic arms 172 and the axial grooves 78 may be any other suitable number, such as 3, 5, etc., without departing from the intended scope of the disclosure.

The spring 74 and the regulator 75 cooperate to automatically adjust the vertical position of the gas phase filter molecular sieve 76 and the liquid phase filter molecular sieve 77, and to reduce relative movement between the gas phase filter molecular sieve 76 and the liquid phase filter molecular sieve 77, thereby reducing the wear between the gas phase filter molecular sieve 76 and the liquid phase filter molecular sieve 77 and lengthening the useful life of the gas phase filter molecular sieve 76 and the liquid phase filter molecular sieve 77. In addition, if the level of the coolant liquid changes (for example, increases), floating force acting on the bottom plate portion 171 also changes, which in turn resists the spring force of the spring 74, thus causing the spring 74 to move (for example, to be further compressed), thus urging the gas phase filter molecular sieve 76 (for example, upward). In this way, the gas phase filter molecular sieve 76 is always above the level of the coolant liquid, thereby preventing failure of the gas phase filter molecular sieve 76 due to immersing in the coolant liquid.

The gas phase filter molecular sieve 76 leaks, and the upper part is exposed to the air, which is used to filter impurities in the air to prevent impurities from dissolving in the coolant liquid, resulting in an increase in the dielectric constant. First, the spring 74 and the regulator 75 are installed in the lower part, and then the liquid phase filter molecular sieve 77 is added and covered with the lower cover 72. The lower part is immersed in the coolant liquid to remove conductive impurities in the coolant liquid. The adjustable spring mechanism is used in the middle to ensure the distribution of the two molecular sieves, and the potential energy of the spring 74 is used to reduce the relative movement between the molecular sieves, thereby reducing the wear between the molecular sieves and causing the molecular sieves to fail.

According to one example, the coolant liquid may be cooling oil. As understood by those skilled in the art, the coolant liquid may be comprised of any other suitable coolant, without departing from the intended scope of the disclosure.

Now, operation of the coolant supply assembly 100 is described. The coolant liquid returns from the heat generation module and flows into the pre-filter device 3 via the coolant inlet 11. The coolant liquid flows through the pre-filter device 3, and the coolant liquid is filtered out of impurities by the pre-filter device 3. The filtered coolant liquid flows to the coolant chamber via the outlet port 132 (FIG. 3). The gas phase filter molecular sieve 76 absorbs impurities and vapor in the air above the coolant liquid to prevent impurities from dissolving in the coolant liquid, resulting in an increase in the dielectric constant of the coolant liquid. The liquid phase filter molecular sieve 77 absorbs moisture and other conductive impurities in the coolant liquid. The pump 5 pumps coolant liquid from the coolant chamber to the heat exchanger 6 via the heat exchanger inlet passage 161, according to the temperature and/or pressure of the coolant liquid in the outlet passage 148. The cooled coolant liquid flows to the annular unfiltered space 43 of main filter device 4 via the heat exchanger outlet passage 162, and flows through the main filter element 42. Cooled and filtered coolant liquid flows through the filter outlet passage 142, the outlet passage 148, and is supplied to the heat generation module via the coolant outlet 12.

Aspects of the present disclosure have been described in detail with reference to the illustrated exemplary embodiments; those skilled in the art will recognize, however, that many modifications may be made thereto without departing from the intended broad scope of the present disclosure. The present disclosure is not limited to the precise construction and compositions disclosed herein; any and all modifications, changes, and variations apparent from the foregoing descriptions are within the intended broad scope of the disclosure, as defined by the appended claims. Moreover, the present concepts expressly include any and all combinations and subcombinations of the preceding elements and features.

That which is claimed is:

1. A coolant supply assembly comprising:
an upper housing comprising a pre-filter mounting portion, a desiccant mounting portion, a pump mounting portion, and a main filter mounting portion on a top surface of the upper housing, the upper housing further comprising a flange portion at a first side surface of the upper housing and a coolant outlet at a second side surface of the upper housing;
a lower housing, the upper housing being mounted to the lower housing to define a coolant chamber;
a pre-filter device mounted to the pre-filter mounting portion;
a desiccant unit mounted to the desiccant mounting portion;
a pump mounted to the pump mounting portion;
a heat exchanger mounted to the flange portion; and
a main filter device mounted to the main filter mounting portion.

2. The coolant supply assembly according to claim 1, wherein the desiccant unit comprises a shell, an upper cover mounted to the shell, a lower cover mounted to the shell, a gas phase filter molecular sieve, and a liquid phase filter molecular sieve, and
wherein the upper cover, the lower cover and the shell form an internal volume, the gas phase filter molecular sieve being disposed in an upper portion of the internal volume, and the liquid phase filter molecular sieve being disposed in a lower portion of the internal volume.

3. The coolant supply assembly according to claim 2, wherein the desiccant unit further comprises a spring and a regulator, the spring and the regulator being configured to cooperate to automatically adjust a vertical position of the gas phase filter molecular sieve and the liquid phase filter molecular sieve.

4. The coolant supply assembly according to claim 3, wherein the regulator comprises a bottom plate portion disposed on top of the liquid phase filter molecular sieve, and a plurality of elastic arms extending axially from the bottom plate portion, an outer diameter of the bottom plate portion being smaller than an inner diameter of the shell, and each of the plurality of elastic arms comprising a projection extending radially outward from an end of a respective one of the plurality of elastic arms, the end being distant from the bottom plate portion,
wherein the shell comprises a plurality of axial grooves for receiving the projection of each of the plurality of elastic arms, respectively, and
wherein the spring is disposed between the bottom plate portion and the gas phase filter molecular sieve.

5. The coolant supply assembly according to claim 1, wherein the desiccant unit has a rectangular cross-section or a circular cross-section.

6. The coolant supply assembly according to claim 1, further comprising a pressure relief valve configured to open a bypass passage upstream of the main filter device, when a pressure upstream of the main filter device exceeds a predetermined pressure.

7. The coolant supply assembly according to claim 1, further comprising a liquid level sensor disposed on the second side surface of the coolant supply assembly and configured to sense a level of coolant liquid in the coolant chamber,
wherein the coolant supply assembly is configured to turn off the pump and trigger an alarm when the level of the coolant liquid is below a predetermined level.

8. The coolant supply assembly according to claim 1, further comprising an electric conductivity sensor disposed in the coolant chamber and configured to sense an electric conductivity of coolant liquid in the coolant chamber,
wherein the coolant supply assembly is configured to turn off the pump and trigger an alarm when the electric conductivity of the coolant liquid exceeds a predetermined electric conductivity.

9. The coolant supply assembly according to claim 1, further comprising an outlet sensor disposed in an outlet passage and configured to sense a temperature and/or a pressure of the coolant liquid in the outlet passage,
wherein the coolant supply assembly is configured to control operation of the pump according to the temperature and/or the pressure of the coolant liquid in the outlet passage.

10. The coolant supply assembly according to claim 1, wherein the coolant supply assembly has a rectangular cross-section comprising the first side surface, the second side surface, a third side surface extending between the first side surface and the second side surface and adjacent to the pre-filter mounting portion, and a fourth side surface opposite to the third side surface, and
wherein the pre-filter mounting portion is located at a corner between the second side surface and the third side surface, the desiccant mounting portion is located at a corner between the second side surface and the fourth side surface, the pump mounting portion is located at a corner between the first side surface and the fourth side surface, and the main filter mounting portion is located at a corner between the first side surface and the third side surface.

11. The coolant supply assembly according to claim 1, wherein the heat exchanger comprises an evaporator.

12. The coolant supply assembly according to claim 1, further comprising a breathing valve.

13. The coolant supply assembly according to claim 1, wherein the main filter device comprises a main filter element disposed within a main filter body with an annular unfiltered space arranged between the main filter body and the main filter element and configured to receive a cooled coolant liquid from the heat exchanger.

14. The coolant supply assembly according to claim 13, wherein the main filter body is provided with threads and the main filter mounting portion is provided with mating threads for mounting the main filter device to the main filter mounting portion by thread engagement.

15. An immersion liquid cooling system comprising the coolant supply assembly according to claim 1.
